(19) United States
(12) Patent Application Publication
(10) Pub. No.: US 2013/0292751 A1
(43) Pub. Date: Nov. 7, 2013

(54) IMAGE SENSOR WITH SEGMENTED ETCH STOP LAYER

(71) Applicants: Gang Chen, San Jose, CA (US); Duli Mao, Sunnyvale, CA (US); Hsin-Chih Tai, San Jose, CA (US)

(72) Inventors: Gang Chen, San Jose, CA (US); Duli Mao, Sunnyvale, CA (US); Hsin-Chih Tai, San Jose, CA (US)

(73) Assignee: OMNIVISION TECHNOLOGIES, INC., Santa Clara, CA (US)

(21) Appl. No.: 13/462,545

(22) Filed: May 2, 2012

(51) Int. Cl. H01L 31/113; H01L 27/146; H01L 31/18

(52) U.S. Cl. 257/292; 438/73; 257/443; 257/E31.083; 257/E27.13

(57) ABSTRACT

An apparatus includes a semiconductor layer having an array of pixels arranged therein. A passivation layer is disposed proximate to the semiconductor layer over the array of pixels. A segmented etch stop layer including a plurality of etch stop layer segments is disposed proximate to the passivation layer over the array of pixels. Boundaries between each one of the plurality of etch stop layer segments are aligned with boundaries between pixels in the array of pixels.

### BACKGROUND INFORMATION

1. Field of the Disclosure

The present invention relates generally to imaging. More specifically, examples of the present invention are related to complementary metal oxide semiconductor based image sensors.

2. Background

The electrical signature of an image with high brightness levels that falls onto a complementary metal oxide semiconductor (CMOS) image sensor may remain embedded in subsequently read out electrical signatures of subsequently acquired images. The electrical signature of a previously sensed image remaining in the image sensor has been called a “ghost artifact” or a “memory effect.” This unwanted effect can be exacerbated by repeated exposure of static images, especially high intensity or bright images, to the image sensor. The retention of ghost images represents noise that obscures subsequently acquired images and reduces the signal to noise ratio and may cause blur if there is movement being imaged.

The memory effect problem has been found to be especially present in CMOS image sensors that have been fabricated using advanced fabrication technologies, particularly those employing measures to maximize metal interconnect density. For instance, those fabrication technologies employing so-called “borderless contacts” have been found to be associated with the root cause of this problem.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a diagram illustrating one example of an imaging system including an example pixel array including a segmented etch stop layer in accordance with the teachings of the present invention.

FIG. 2A illustrates a top down view of one example of an example pixel array in accordance with the teachings of the present invention.

FIG. 2B illustrates a top down view of one example of segmenting an etch stop layer in an example pixel array in accordance with the teachings of the present invention.

FIG. 3A illustrates a cross-section view of one example of a semiconductor substrate layer included in an example pixel array in accordance with the teachings of the present invention.

FIG. 3B illustrates a cross-section view of one example of a passivation layer deposited over a semiconductor substrate layer included in an example pixel array in accordance with the teachings of the present invention.

FIG. 3C illustrates a cross-section view of one example of an etch stop layer deposited over a passivation layer deposited over a semiconductor substrate layer included in an example pixel array in accordance with the teachings of the present invention.

FIG. 3D illustrates a cross-section view of one example of segmenting an etch stop layer deposited over a passivation layer deposited over a semiconductor substrate layer included in an example pixel array in accordance with the teachings of the present invention.

FIG. 3E illustrates a cross-section view of another example of segmenting an etch stop layer deposited over a passivation layer deposited over a semiconductor substrate layer included in an example pixel array in accordance with the teachings of the present invention.

FIG. 3F illustrates a cross-section view of one example of a metal interconnect layer disposed proximate to segmented etch stop layer deposited over a passivation layer deposited over a semiconductor substrate layer included in an example pixel array in accordance with the teachings of the present invention.

FIG. 4 is an example flow chart diagram illustrating an example method of fabricating a CMOS image sensor including an example segmented etch stop layer in accordance with the teachings of the present invention.

FIG. 5A shows an example of an original image acquired by an imaging system.

FIG. 5B shows an example of an image from an imaging system without a segmented etch stop layer showing symptoms of memory effect.

FIG. 5C shows an example of an image in an imaging system including a segmented etch stop layer in accordance with the teachings of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

Examples in accordance with the teaching of the present address a contributing factor among the root causes for memory effect in complementary metal oxide semiconductor (CMOS) image sensors and provide solutions to reduce or eliminate memory effect in CMOS image sensors that include etch stop layers. Example CMOS image sensors in accordance with the teachings of the present invention include an example contact etch stop layer, which makes possible borderless contact elements in CMOS image sensor with reduced or no memory effect. Specifically, instead of providing a continuous contact etch stopping layer over the entire surface of an image sensor, except where a contact opening has been designated to interconnect two conducting layers, example image sensors in accordance with the teachings of the present include a contact etch stop layer that is segmented around the periphery of each pixel or segmented around the periphery of a group of pixels. The segmentation or removal of the contact etch stop layer material between the pixels in the image sensor may provide an electrical and/or a mechanical effect on the pixel, which reduces ghost artifacts or memory effect in image sensors in accordance with the teachings of the present invention.

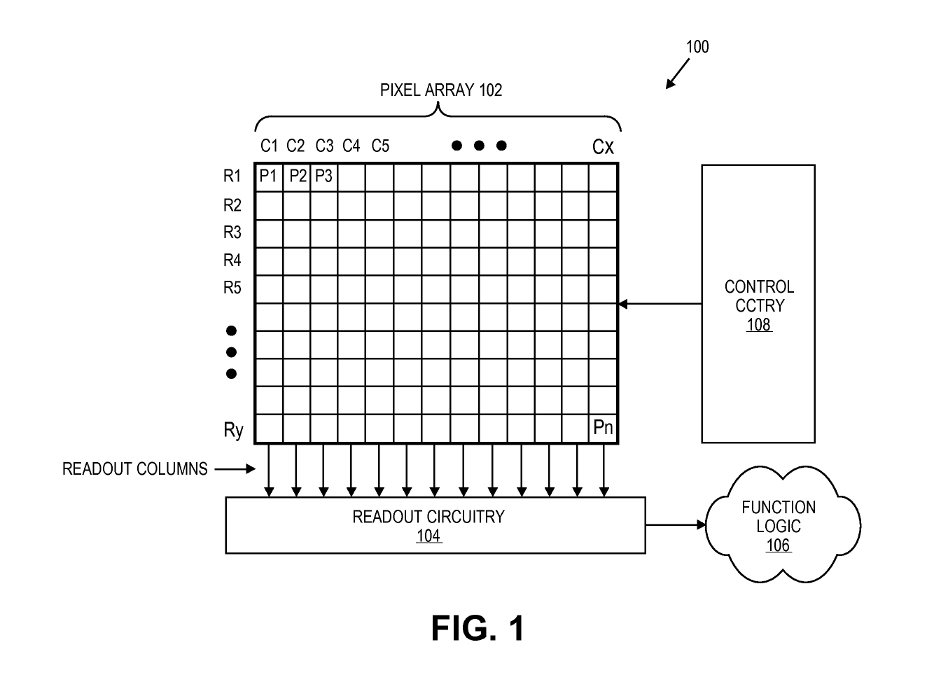

FIG. 1 is a diagram illustrating one example of an imaging system 100 including an example pixel array 102 having a segmented etch stop layer in accordance with the teachings of the present invention. As shown in the depicted example, imaging system 100 includes pixel array 102 coupled to control circuitry 108 and readout circuitry 104, which is coupled to function logic 106.

In one example, pixel array 102 is a two-dimensional (2D) array of imaging sensors or pixels (e.g., pixels P1, P2 . . . Pn). In one example, each pixel is a CMOS imaging pixel. As illustrated, each pixel is arranged into a row (e.g., rows R1 to Ry) and a column (e.g., column C1 to Cx) to acquire image data of a person, place, object, etc., which can then be used to render a 2D image of the person, place, object, etc.

In one example, after each pixel has acquired its image data or image charge, the image data is readout by readout circuitry 104 and then transferred to function logic 106. In various examples, readout circuitry 104 may include amplification circuitry, analog-to-digital (ADC) conversion circuitry, or otherwise. Function logic 106 may simply store the image data or even manipulate the image data by applying post image effects (e.g., crop, rotate, remove red eye, adjust brightness, adjust contrast, or otherwise). In one example, readout circuitry 104 may readout a row of image data at a time along readout column lines (illustrated) or may readout the image data using a variety of other techniques (not illustrated), such as a serial readout or a full parallel readout of all pixels simultaneously.

In one example, control circuitry 108 is coupled to pixel array 102 to control operational characteristics of pixel array 102. For example, control circuitry 108 may generate a shutter signal for controlling image acquisition. In one example, the shutter signal is a global shutter signal for simultaneously enabling all pixels within pixel array 102 to simultaneously capture their respective image data during a single acquisition window. In another example, the shutter signal is a rolling shutter signal such that each row, column, or group of pixels is sequentially enabled during consecutive acquisition windows.

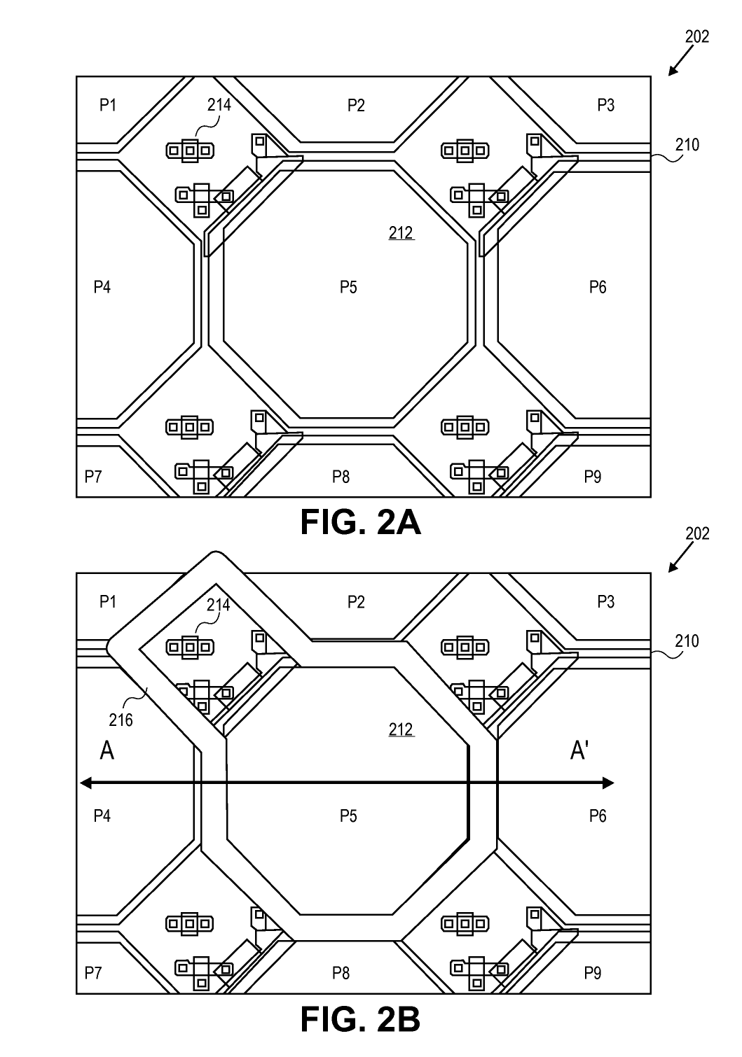

FIG. 2A illustrates a top down view of one example of a semiconductor substrate 210 of an example pixel array 202 in accordance with the teachings of the present invention. It is appreciated that in one example, pixel array 202 is an illustration that provides increased detail of example pixel array 102 of FIG. 1. As shown in the example depicted in FIG. 2A, pixel array 202 includes semiconductor substrate 210 having an array of pixels (e.g. P1, P2, P3, P4, P5, P6, P7, P8, P9, . . . ) arranged therein. As shown in the example, each pixel, such as for example pixel P5 as illustrated in FIG. 2A, includes a photodiode 212 as well as associated pixel circuitry 214 coupled to photodiode 212 arranged in pixel array 202 in semiconductor substrate 210. In one example, pixel circuitry 214 may include pixel circuit elements such as for example but not limited to a transfer transistor and a floating diffusion. In one example, one or more pixels may also include or share a charge to voltage converting floating diode and an amplifier transistor.

As will be discussed in further detail below, in one example, an etch stop layer is also deposited over pixel array 202. The deposition of an etch stop layer is a fabrication technique that may be utilized when providing borderless contacts, which may be employed to increase metal interconnect density in pixel array 202. In one example, the etch stop layer is segmented around the periphery of each pixel, or around the periphery of a group of pixels, such that boundaries between each one of a plurality of etch stop layer segments are aligned with boundaries between the pixels arranged in pixel array 202 in accordance with the teachings of the present invention.

To illustrate, FIG. 2B illustrates a top down view of one example of a relative location of where an etch stop layer is segmented in an example pixel array 202 in accordance with the teachings of the present invention. As shown in the example and will be discussed in further detail below, a boundary 216 around the periphery of pixel P5, which includes photodiode 212 and pixel circuitry 214, is where portions of the etch stop layer that is disposed over pixel array 202 may be removed, which segments the etch stop layer into a plurality of separated etch stop layer segments in accordance with the teachings of the present invention. Thus, in the specific example illustrated in FIG. 2B, boundary 216 is aligned with the boundary around pixel P5 and/or aligned with the boundaries between pixel P5 neighboring pixels in pixel array 202 in accordance with the teachings of the present invention. It is appreciated that by changing the structure of pixel array 202 with the separation of the etch stop layer into a plurality of etch stop layer segments over pixel array 202 around the periphery of each pixel or group of pixels, additional electrical and/or mechanical effects on the pixels are realized, which reduces ghost artifacts or memory effects in pixel array 202 in accordance with the teachings of the present invention.

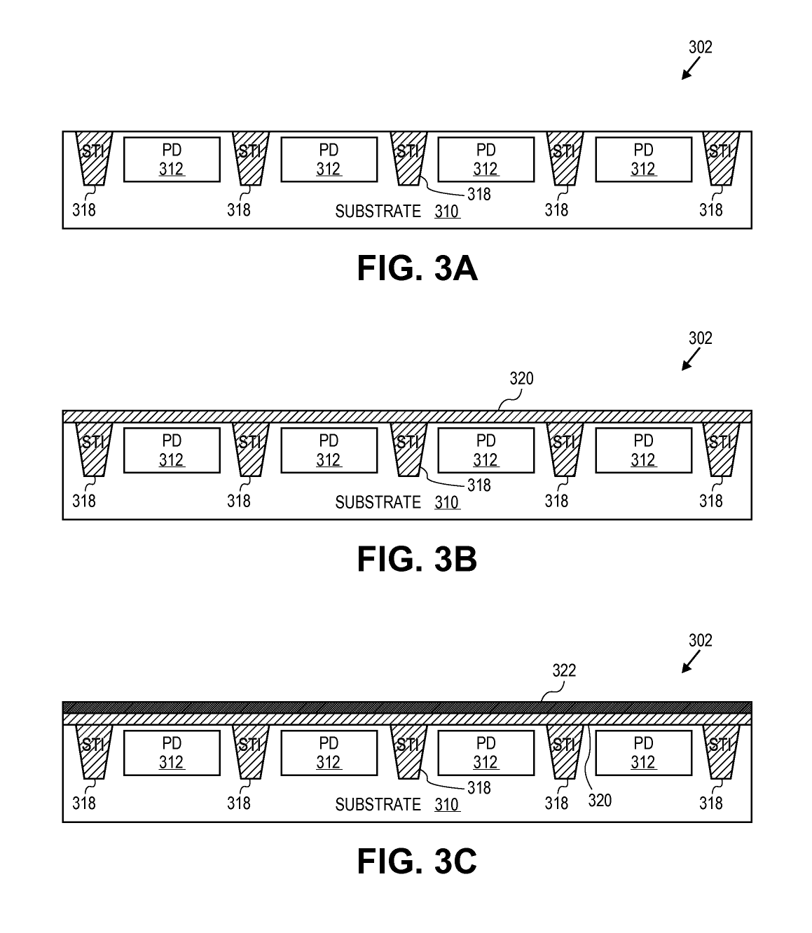

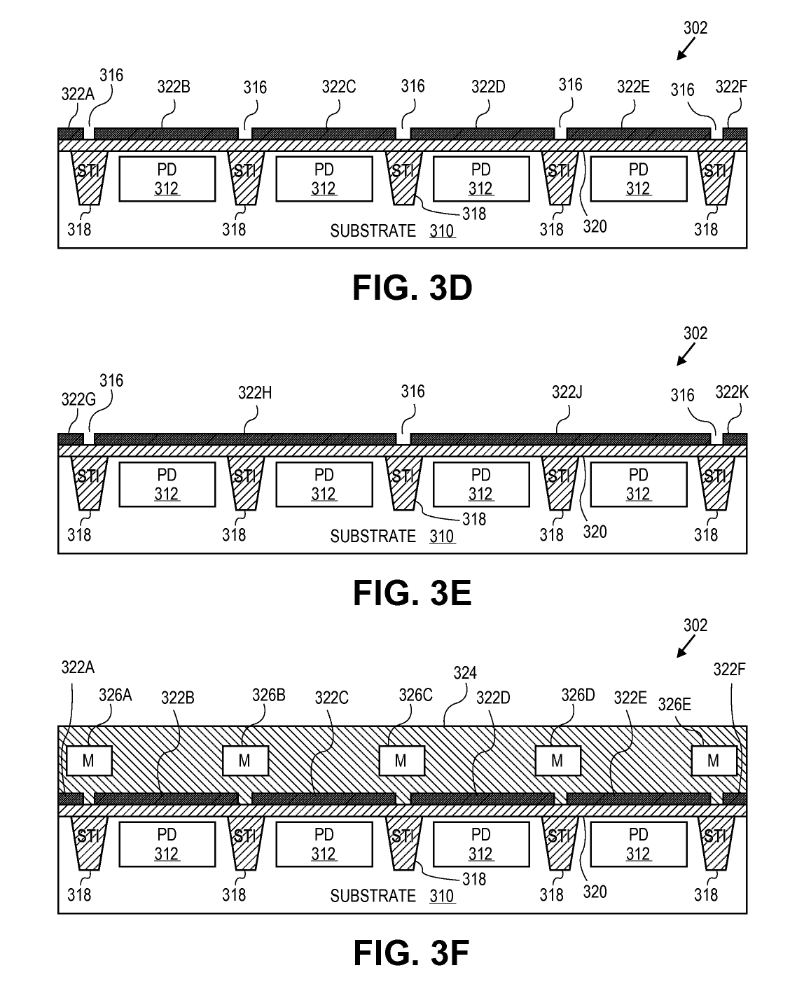

FIG. 3A illustrates a cross-section view of one example of a semiconductor substrate layer 310 included in an example pixel array 302 of a CMOS image sensor in accordance with the teachings of the present invention. It is noted that in one example, pixel array 302 is a cross-section view along line A-A′ of pixel array 202 of FIG. 2B. As shown in the depicted example, pixel array 302 includes a semiconductor substrate layer 310, including for example silicon, with a plurality of photodiode regions 312 arranged therein. In the example, each one of the plurality of photodiode regions 312 is included in a separate pixel of pixel array 302. As shown in the depicted example, there are shallow trench isolation (STI) 318 regions separating neighboring photodiode regions 312 in the semiconductor substrate layer 310, which therefore define boundaries between the pixels of pixel array 302.

FIG. 3B illustrates a cross-section view of one example of a passivation layer 320 deposited over semiconductor substrate layer 310 of example pixel array 302 in accordance with the teachings of the present invention. In one example, passivation layer 320 may include insulating material such as for example silicon oxide based dielectric layers or the like.

FIG. 3C illustrates a cross-section view of one example of an etch stop layer 322 that is deposited over passivation layer 320, which is deposited over semiconductor substrate layer 310 included in example pixel array 302 in accordance with the teachings of the present invention. In one example, etch stop layer 322 is a contact etch stop layer that will be utilized when providing borderless contacts to be fabricated in pixel array 302. As such, etch stop layer 322 will be used to protect underlying structures from damage during the dry etching process that will be used later to form contact openings. Accordingly, etch stop layer 322 has a slower etch rate than for example silicon oxide based dielectric layers.

In one example, etch stop layer 322 may include a silicon nitride based dielectric including for example silicon oxynitride or silicon carbide or the like. In one example, etch stop layer 322 may be deposited using a plasma enhanced chemical vapor deposition (PECVD), which employs an electrically driven plasma to breakdown source gases such as Silane (SiH₄), ammonia (NH₄) and oxygen (O₂) to provide sources of silicon, nitrogen and oxygen for the formation of silicon nitride and/or silicon oxynitride.

In one example, the resulting etch stop layer 322 may therefore be characterized by including significant amounts of mobile charge due to residual hydrogen or poorly formed crystallographic bonding between atoms, such as for example Si—Si bonds or Si—H bonds. In one example, the resulting etch stop layer 322 is also characterized by having residual mechanical stress associated with the chosen deposition process parameters or the chosen relative quantities of the reacting gases.

The mobile charges in the PECVD silicon nitride and/or silicon oxynitride of etch stop layer 322 can be moved by electrical forces such as electrical fields placed across etch stop layer 322, which can cause unwanted effects in nearby semiconductor regions, such as photodiode regions 312 and/or the pixel circuitry included in the pixels of pixel array 302. For example, the source to drain resistance of a transistor included in the pixel circuitry included in the pixels of pixel array 302 may be affected by the mobile charge in the overlying PECVD silicon nitride of etch stop layer 322 by altering the depletion characteristics of an underlying lightly doped source or drain region. In addition, it is noted that the interface between the PECVD silicon nitride and/or silicon oxynitride of etch stop layer 322 and other films, such as silicon dioxide films, are capable of holding charges typically in broken bonds between various atoms at the interfaces.

Furthermore, it is noted that net positive charges can be induced in the PECVD silicon nitride and/or silicon oxynitride of etch stop layer 322 by exposure to visible light, which can occur when photodiode regions 312 of pixel array 302 are illuminated. In particular, the energy associated with the phonon modes of the Si—Si and Si—H crystal structures may participate in the optical excitation of the electrical carriers. Phonons are a property associated with the crystal structure and therefore likely are tied to the stress property of the PECVD silicon nitride and/or silicon oxynitride of etch stop layer 322.

All of above summarized charge-related characteristics of the PECVD silicon nitride and/or silicon oxynitride of etch stop layer 322 can cause unwanted effects in semiconductor regions nearby, and therefore contribute to unwanted ghost artifacts or memory effects in pixel array 302.

In order to address the unwanted ghost artifacts or memory effects in pixel array 302 that may be caused by etch stop layer 322, FIG. 3D illustrates a cross-section view of one example of segmenting etch stop layer 322 deposited over passivation layer 320, which is deposited over semiconductor substrate layer 310 included in example pixel array 302 in accordance with the teachings of the present invention. In particular, FIG. 3D shows that portions 316 are trenched or removed from etch stop layer 322 between pixels to result in etch stop layer 322 being separated into a plurality of etch stop layer segments. In one example, the trenches that define portions 316 are as narrow as possible to reduce the possibility of damaging the surfaces of photodiode regions 312 arranged in semiconductor substrate layer 310. In FIG. 3D, the plurality of etch stop layer segments are illustrated as etch stop layer segments 322A, 322B, 322C, 322D, 322E and 322F. As shown in the depicted example, the boundaries between etch stop layer segments 322A, 322B, 322C, 322D, 322E and 322F are aligned with the boundaries between the pixels in the pixel array 302, which in one example are defined at STI 318 locations in semiconductor substrate layer 310.

By segmenting etch stop layer 322 into a plurality of etch stop layer segments 322A, 322B, 322C, 322D, 322E and 322F as shown, the memory effect is reduced or eliminated in pixel array 302 in accordance with the teachings of the present invention. The segmenting of etch stop layer 322 as shown may reduce the memory effect in pixel array 302 because the stress otherwise present in etch stop layer 322 has been released by the removal of portions 316, which therefore reduces the propensity of etch stop layer 322 to become optically excited and hold ghost artifact images through charge trapping within etch stop layer 322 or at interfaces of etch stop layer 322 with adjacent films, including for example passivation layer 320. In addition, it is noted that the memory effect may also be reduced in pixel array 302 because the trenching performed when removing portions 316 from etch stop layer 322 may result in an overall reduction of mobile charge within etch stop layer 322, which also reduces memory effect in pixel array 302 in accordance with the teachings of the present invention.

It is noted that in FIG. 3D, each one of the etch stop layer segments 322A, 322B, 322C, 322D, 322E and 322F overlaps a single pixel below. FIG. 3E illustrates a cross-section view of another example of segmenting etch stop layer 322 deposited over passivation layer 320, which is deposited over semiconductor substrate layer 310 included pixel array 302 in accordance with the teachings of the present invention. In particular, FIG. 3E shows that portions 316 of etch stop layer 322 are trenched or removed between pixels to result in a plurality of etch stop layer segments 322G, 322H, 322J and 322K as shown. A difference between the example illustrated in FIG. 3E and the example shown in FIG. 3D is that the in the example shown in FIG. 3E, etch stop layer segments 322H and 322J each overlap a plurality of pixels below in accordance with the teachings of the present invention. In other words, each etch stop layer segment may overlap a single pixel or each etch stop layer segment may overlap a plurality of pixels in accordance with the teachings of the present invention.

FIG. 3F illustrates a cross-section view of one example of a metal interconnect layer 324 that is later disposed proximate to segmented etch stop layer 322 deposited over passivation layer 320, which is deposited over semiconductor substrate layer 310 included in example pixel array 302 in accordance with the teachings of the present invention. In one example, metal interconnect layer 324 is a metal stack layer that includes a plurality of metal interconnects 326A, 326B, 326C, 326D and 326E that provide electrical connections to the pixel circuitry in the pixel array 302. In one example, metal interconnects 326A, 326B, 326C, 326D and 326E include one more borderless contacts in accordance with the teachings of the present invention. In another example, none of the metal interconnects 326A, 326B, 326C, 326D and 326E are borderless contacts in accordance with the teachings of the present invention.

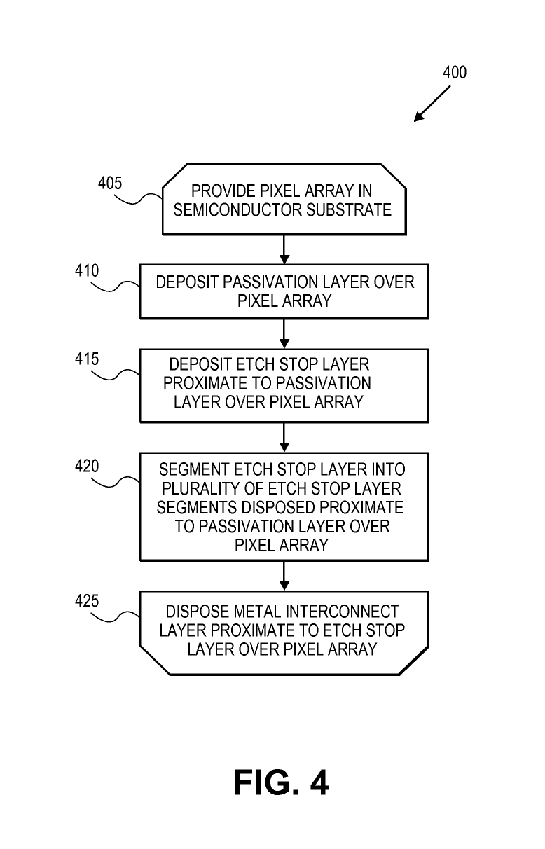

FIG. 4 is an example flow chart diagram illustrating an example process 400 of fabricating a CMOS image sensor including an example segmented etch stop layer in accordance with the teachings of the present invention. As show in the depicted example, process block 405 shows that a pixel array is provided in a semiconductor substrate. In one example, the pixel array includes a plurality of pixels and each one of the plurality of pixels includes a photodiode and pixel circuitry coupled to the photodiode disposed in the semiconductor substrate.

Process block 410 shows that a passivation layer is deposited proximate to the semiconductor substrate over the pixel array.

Process block 415 shows that an etch stop layer is deposited proximate to the passivation layer over the pixel array.

Process block 420 shows that the etch stop layer is segmented into a plurality of etch stop layer segments disposed proximate to the passivation layer over the pixel array. In one example, boundaries between each one of the plurality of etch stop layer segments are aligned with boundaries between pixels in the pixel array. In one example, segmenting the etch stop layer into the plurality of etch stop layer segments includes etching away portions of the etch stop layer between pixels in the pixels array. In another example, each one of the plurality of etch stop layer segments overlaps a corresponding one of the pixels in the pixel array. In another example, each one of the plurality of etch stop layer segments overlaps a plurality of pixels in the pixel array.

Process block 425 shows that a metal interconnect layer is then disposed proximate to the etch stop layer over the pixel array. In one example, disposing the metal interconnect layer comprises forming borderless contacts in the metal interconnect layer to provide electrical connections to the pixel circuitry in the pixel array.

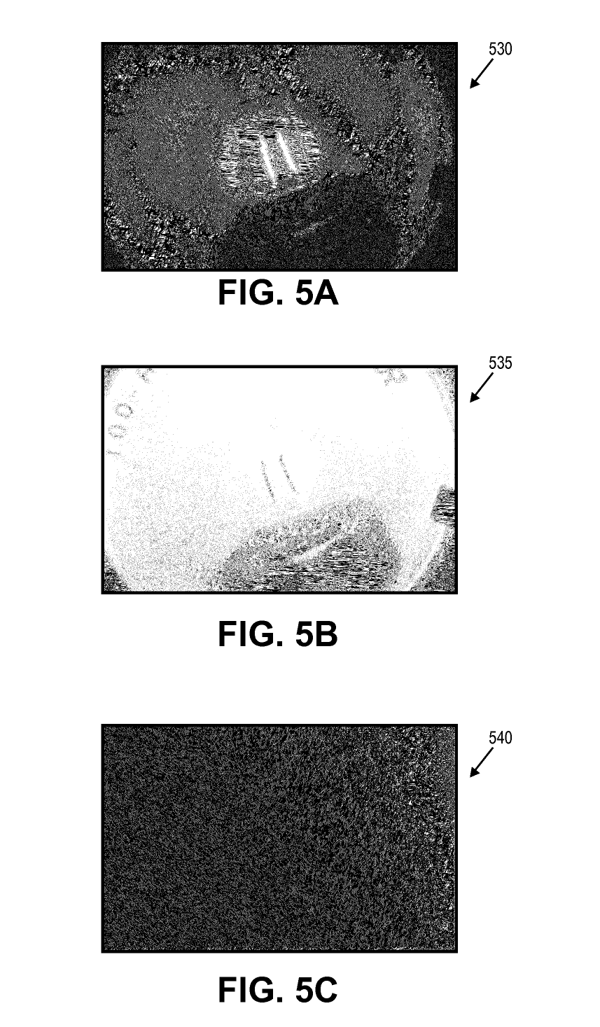

FIGS. 5A-5C are example images that illustrate memory effect in an pixel array and the reduction of that memory effect in a pixel array including a segmented etch stop layer in accordance with the teachings of the present invention. In particular, FIG. 5A shows an example of an original image 530 acquired by an imaging system. FIG. 5B shows an example of an image 535 from an imaging system without a segmented etch stop layer, and consequently showing the symptoms of memory effect. FIG. 5C shows an example of an image 540 in an imaging system including a segmented etch stop layer in accordance with the teachings of the present invention. As shown in FIG. 5C, there is no memory effect in image 540 in accordance with the teachings of the present invention.

The above description of illustrated examples of the present invention, including what is described in the Abstract, are not intended to be exhaustive or to be limitation to the precise forms disclosed. While specific embodiments of, and examples for, the invention are described herein for illustrative purposes, various equivalent modifications are possible without departing from the broader spirit and scope of the present invention. Indeed, it is appreciated that the specific example voltages, currents, frequencies, power range values, times, etc., are provided for explanation purposes and that other values may also be employed in other embodiments and examples in accordance with the teachings of the present invention.

What is claimed is:

1. An apparatus, comprising:
a semiconductor layer having an array of pixels arranged therein;
a passivation layer disposed proximate to the semiconductor layer over the array of pixels; and
a segmented etch stop layer including a plurality of etch stop layer segments disposed proximate to the passivation layer over the array of pixels, wherein boundaries between each one of the plurality of etch stop layer segments are aligned with boundaries between pixels in the array of pixels.

2. The apparatus of claim 1 wherein each one of the plurality of etch stop layer segments overlaps a corresponding one of the pixels in the array of pixels.

3. The apparatus of claim 1 wherein each one of the plurality of etch stop layer segments overlaps a plurality of pixels in the array of pixels.

4. The apparatus of claim 1 further comprising a metal interconnect layer disposed proximate to the segmented etch stop layer over the array of pixels.

5. The apparatus of claim 4 wherein the metal layer includes borderless contacts disposed therein.

6. The apparatus of claim 1 wherein the boundaries between each one of the plurality of etch stop layer segments are defined in regions of removed portions of the segmented etch stop layer between pixels in the array of pixels.

7. The apparatus of claim 1 wherein the boundaries between pixels in the array of pixels are defined along shallow trench isolation regions between pixels in the array of pixels.

8. The apparatus of claim 1 wherein the segmented etch stop layer comprises nitride.

9. The apparatus of claim 1 wherein the segmented etch stop layer comprises silicon oxynitride.

10. The apparatus of claim 1 wherein the passivation layer comprises oxide.

11. The apparatus of claim 1 wherein the apparatus is comprised in a complementary metal oxide semiconductor (CMOS) image sensor.

12. The apparatus of claim 1 wherein each one of the pixels in the array of pixels comprises a photodiode.

13. A method of fabricating a complementary metal oxide semiconductor (CMOS) image sensor, comprising:
providing a pixel array in a semiconductor substrate, the pixel array comprising a plurality of pixels, wherein each one of the plurality of pixels includes a photodiode and pixel circuitry coupled to the photodiode disposed in the semiconductor substrate;
depositing a passivation layer proximate to the semiconductor substrate over the pixel array;
depositing an etch stop layer proximate to the passivation layer over the pixel array;
segmenting the etch stop layer into a plurality of etch stop layer segments disposed proximate to the passivation layer over the pixel array, wherein boundaries between each one of the plurality of etch stop layer segments are aligned with boundaries between pixels in the pixel array; and
disposing a metal interconnect layer proximate to the etch stop layer over the pixel array.

14. The method of claim 13 wherein segmenting the etch stop layer into the plurality of etch stop layer segments comprises etching away portions of the etch stop layer between pixels in the pixels array.

15. The method of claim 13 wherein disposing the metal interconnect layer comprises forming borderless contacts in the metal interconnect layer to provide electrical connections to the pixel circuitry in the pixel array.

16. An imaging system, comprising:
a pixel array including:
a semiconductor layer having a plurality of pixels arranged therein;
a passivation layer disposed proximate to the semiconductor layer over the plurality of pixels; and
a segmented etch stop layer including a plurality of etch stop layer segments disposed proximate to the passivation layer over the plurality of pixels, wherein boundaries between each one of the plurality of etch stop layer segments are aligned with boundaries between pixels of the plurality of pixels;
control circuitry coupled to the pixel array to control operation of the pixel array; and
readout circuitry coupled to the pixel array to readout image data from the plurality of pixels.

17. The imaging system of claim 16 further comprising function logic coupled to the readout circuitry to store the image data readout from the plurality of pixels.

18. The imaging system of claim 16 wherein the each one of the plurality of etch stop layer segments overlaps a corresponding one of the pixels of the plurality of pixels.

19. The imaging system of claim 16 wherein each one of the plurality of etch stop layer segments overlaps at least two pixels of the plurality of pixels.

20. The imaging system of claim 16 further comprising a metal layer disposed proximate to the segmented etch stop layer over the plurality of pixels.

21. The imaging system of claim 20 wherein the metal layer includes borderless contacts disposed therein.

22. The imaging system of claim 16 wherein the boundaries between each one of the plurality of etch stop layer segments are defined in regions of removed portions of the segmented etch stop layer between pixels in the plurality of pixels.

23. The imaging system of claim 16 wherein the segmented etch stop layer comprises nitride.

24. The imaging system of claim 16 wherein the segmented etch stop layer comprises silicon oxynitride.

25. The imaging system of claim 16 wherein the passivation layer comprises oxide.
